(19) United States
(12) Patent Application Publication
(10) Pub. No.: US 2019/0027936 A1
(43) Pub. Date: Jan. 24, 2019

(54) POWER SUPPLY CONTROL METHOD AND SYSTEM

(71) Applicant: HYOSUNG HEAVY INDUSTRIES CORPORATION, Seoul (KR)

(72) Inventors: Se Chang KIM, Ansan-si, Gyeonggi-do (KR); Bo Gun JIN, Anyang-si, Gyeonggi-do (KR)

(21) Appl. No.: 16/067,423

(22) PCT Filed: Dec. 23, 2016
(86) PCT No.: PCT/KR2016/015207

§ 371 Date: Jun. 29, 2018

(30) Foreign Application Priority Data
Dec. 30, 2015 (KR) 10-2015-0190185

(51) Int. Cl. H02J 3/32; G05F 1/66; G05B 13/04; G06Q 50/06; G01R 19/165

(52) U.S. Cl. CPC H02J 3/32; G05F 1/66; G05B 13/048; H02J 2007/0067; G06Q 50/06; G01R 19/16542; G01R 19/16547; G05B 13/041

(57) ABSTRACT

Provided is a power supply control method and system capable of efficiently adjusting an ESS charge/discharge operation on the basis of a load measurement value and a power generation amount measurement value. The power supply control system includes: a power generation amount measurement unit configured to measure a current power generation amount value; a power generation amount forecast unit configured to forecast a power generation amount value; a load measurement unit configured to measure a current load value; a load forecast unit configured to forecast a load value; a correction value computation unit configured to correct at least one of a peak cut value, a load leveling value, the forecasted power generation amount, and the load forecast value on the basis of at least one of a difference between the power generation amount measurement unit and the power generation amount forecast unit and a difference between the load measurement unit and the load forecast unit; and an ESS charge/discharge operation output control unit configured to control an output of an ESS charge/discharge operation by applying a correction value computed by the correction value computation unit.

### TECHNICAL FIELD

The present invention relates to a power supply control method and system, and more particularly, to a power supply control method and system using an energy storage system (ESS). That is, the present invention relates to a power supply control method and system capable of efficiently adjusting an ESS charge/discharge operation by correcting a peak cut value and a load leveling value computed from a load forecast value and a forecasted power generation amount on the basis of a measurement value.

### BACKGROUND ART

A smart grid is regarded as a next generation intelligence power network capable of optimizing energy efficiency by exchanging information bidirectionally between power suppliers and consumers in real time and incorporating information technology into an existing power network. In such a smart grid, an energy storage system (ESS) is provided along with an energy generation system based no renewable energy such as solar energy or wind energy. The smart grid is evolving to a system for allowing consumer groups (such as houses, buildings, and factories) to store and consume electric power.

In this regard, various methods have been studied and developed in order to efficiently use electric power using the ESS. For example, in the technique of Korean Patent Application Publication No. 10-2012-0135394, a driving mode of the ESS is determined on the basis of a power relationship between batteries, renewable energy, and grid power in response to a battery charge/discharge control signal received from an energy management system, and the determined driving mode is transmitted to the energy management system. In addition, the battery charge/discharge operation is performed in response to the battery charge/discharge operation control signal, and the control is performed such that a power relationship between batteries, renewable energy, and the power grid becomes zero at a DC-link, in order to automatically determine the driving mode of the energy storage system.

However, even in this case, the ESS charge/discharge operation is automatically driven on the basis of a schedule computed from a load value and a renewable power generation amount forecasted a day ago. Therefore, the operation is made by applying a peak cut value and a load leveling value set in advance regardless of a field situation not in real time. Accordingly, it is difficult to appropriately decrease a load consumption peak value and maximize an activity ratio of the ESS.

### SUMMARY OF INVENTION

It is therefore an object of the invention to provide a power supply control method and system capable of effectively decreasing a load consumption peak value and maximizing an activity ratio of the ESS by adjusting the peak cut value and the load leveling value depending on a field situation on the basis of the current load measurement value and the power generation amount measurement value.

Another object of the invention is to provide a power supply control method and system capable of improving accuracy for setting the peak cut value and the load leveling value on the basis of the load forecast value and the power generation amount forecast value by correcting the load forecast value and the power generation amount forecast value computed in advance from the current load measurement value and the current power generation amount measurement value.

According to an aspect of the invention, there is provided a power supply control method including: a measurement process for measuring a power generation amount and a load value; a comparison process for comparing the power generation amount and the load value measured by the measurement process with a forecasted power generation amount and a load forecast value forecasted in advance; a correction value computation process for correcting at least one of, a peak cut value, a load leveling value, the forecasted power generation amount, and the load forecast value on the basis of a result of the comparison of the comparison process; and an energy storage system (ESS) charge/discharge operation output control process for controlling an output of an ESS charge/discharge operation by applying a correction value computed in the correction value computation process.

In the power supply control method described above, the correction value computation process may have a battery discharge measurement value comparison process for checking whether or not a battery discharge measurement value is smaller than the battery discharge forecast value, a predicted remaining supply amount determination process for checking whether or not a predicted remaining amount after battery discharge is larger than an additional discharge amount in a peak cut-down operation, and a peak cut decreasing process for decreasing the peak cut value by a predetermined level if the battery discharge measurement value is smaller than the battery discharge forecast value, and the predicted remaining amount after battery discharge is larger than the additional discharge amount in the peak cut-down operation.

In the power supply control method described above, the correction value computation process may have a battery discharge measurement value comparison process for checking whether or not the battery discharge measurement value is larger than the battery discharge forecast value, a predicted supply deficiency amount determination process for checking whether or not a predicted battery supply deficiency amount is larger than a discharge reduction amount in a peak cut-up operation, and a peak cut increasing process for increasing the peak cut value by a predetermined level if the battery discharge measurement value is larger than the battery discharge forecast value, and the predicted battery supply deficiency amount is larger than the discharge reduction amount in the peak cut-up operation.

In the power supply control method described above, the correction value computation process may have a battery charge measurement value comparison process for checking whether or not a battery charge measurement value is larger than a battery charge forecast value, a predicted battery overcharge amount determination process for checking whether or not a predicted battery overcharge amount is larger than the a charge reduction amount in a load leveling-down operation, and a load leveling decreasing process for decreasing the load leveling value by a predetermined level if the battery charge measurement value is larger than the battery charge forecast value, and the predicted battery overcharge amount is larger than the charge reduction amount in the load leveling-down operation.

In the power supply control method described above, the correction value computation process may have a battery charge measurement value comparison process for checking whether or not a battery charge measurement value is smaller than a battery charge forecast value, a predicted charge deficiency amount determination process for checking whether or not a predicted battery deficiency charge amount is larger than an additional charge amount in a load leveling-up operation, and a load leveling increasing process for increasing the load leveling value by a predetermined level if the battery charge measurement value is smaller than the battery charge forecast value, and the predicted battery deficiency charge amount is larger than an additional charge amount in the load leveling-up operation.

In the power supply control method described above, the correction value computation process may have a load forecast value upper limit excess check process for checking whether or not an accumulated error of the load forecast value is larger than an upper limit reference value, and a load forecast value decreasing process for decreasing the load forecast value by a predetermined level if the accumulated error of the load forecast value is larger than the upper limit reference value.

In the power supply control method described above, the correction value computation process may have a load forecast value lower limit shortage check process for checking whether or not an accumulated error of the load forecast value is smaller than a lower limit reference value, and a load forecast value increasing process for increasing the load forecast value by a predetermined level if the accumulated error of the load forecast value is smaller than the lower limit reference value.

In the power supply control method described above, the correction value computation process may have a forecasted power generation amount upper limit excess check process for checking whether or not an accumulated error of the forecasted power generation amount is larger than an upper limit reference value, and a forecasted power generation amount decreasing process for decreasing the forecasted power generation amount by a predetermined level if the accumulated error of the forecasted power generation amount is larger than the upper limit reference value.

In the power supply control method described above, the correction value computation process may have a forecasted power generation amount lower limit shortage check process for checking whether or not an accumulated error of the forecasted power generation amount is smaller than a lower limit reference value, and a forecasted power generation amount increasing process for increasing the forecasted power generation amount by a predetermined level if the accumulated error of the forecasted power generation amount is smaller than the lower limit reference value.

According to another aspect of the invention, there is provided a power supply control system including: a power generation amount measurement unit configured to measure a current power generation amount value; a power generation amount forecast unit configured to forecast a power generation amount value; a load measurement unit configured to measure a current load value; a load forecast unit configured to forecast a load value; a correction value computation unit configured to correct at least one of a peak cut value, a load leveling value, the forecasted power generation amount, and the load forecast value on the basis of at least one of a difference between the power generation amount measurement unit and the power generation amount forecast unit and a difference between the load measurement unit and the load forecast unit; and an ESS charge/discharge operation output control unit configured to control an output of an ESS charge/discharge operation by applying a correction value computed by the correction value computation unit.

Using the power supply control method and system according to the present invention, it is possible to effectively decrease a load consumption peak value and maximize an activity ratio of the ESS by adjusting the peak cut value and the load leveling value depending on a field situation on the basis of the current load measurement value and the current power generation amount measurement value.

In addition, it is possible to improve accuracy of the load forecast value and the power generation amount forecast value by correcting the load forecast value and the power generation amount forecast value computed in advance on the basis of the current load measurement value and the current power generation amount measurement value.

### BRIEF DESCRIPTION OF DRAWINGS

FIG. 1 is a block diagram illustrating a power supply control system according to an embodiment of the invention;

FIG. 2 is a graph illustrating a load forecast value, a peak cut value, a load leveling value set in advance before ESS operation;

FIG. 3 is a graph illustrating a case where the load measurement value is larger than the load forecast value after ESS operation;

FIG. 4 is a graph illustrating a case where the load measurement value is smaller than the load forecast value after ESS operation;

FIG. 5 is a flowchart illustrating a power supply control method according to an embodiment of the invention;

FIG. 6 is a graph for describing a method of performing a peak cut-down operation through correction in the correction value computation process of FIG. 5;

FIG. 7 is a flowchart for describing a method of performing a peak cut-down operation through correction in the correction value computation process of FIG. 5;

FIG. 8 is a graph for describing a method of performing a peak cut-up operation through correction in the correction value computation process of FIG. 5;

FIG. 9 is a flowchart for describing a method of performing a peak cut-up operation through correction in the correction value computation process of FIG. 5;

FIG. 10 is a graph for describing a method of performing a load leveling-down operation through correction in the correction value computation process of FIG. 5;

FIG. 11 is a flowchart for describing a method of performing a load leveling-down operation through correction in the correction value computation process of FIG. 5;

FIG. 12 is a graph for describing a method of performing a load leveling-up operation through correction in the correction value computation process of FIG. 5;

FIG. 13 is a flowchart for describing a method of performing a load leveling-up operation through correction in the correction value computation process of FIG. 5;

FIG. 14 is a flowchart for describing a method of adjusting a load forecast value through correction in the correction value computation process of FIG. 5; and

FIG. 15 is a flowchart for describing a method of adjusting a forecasted power generation amount through correction in the correction value computation process of FIG. 5.

### DESCRIPTION OF EMBODIMENTS

Embodiments for embodying the invention will now be described with reference to the accompanying drawings.

Since the present invention may be modified or embodied in various forms, particular embodiments will be described in detail with reference to the accompanying drawings. However, it should be noted that they are not intended to limit the invention, but include all possible all possible modifications, equivalents, and substitutes within the scope and spirit of the present invention.

A power supply control method and system according to the present invention will now be described in details with reference to the accompanying drawings.

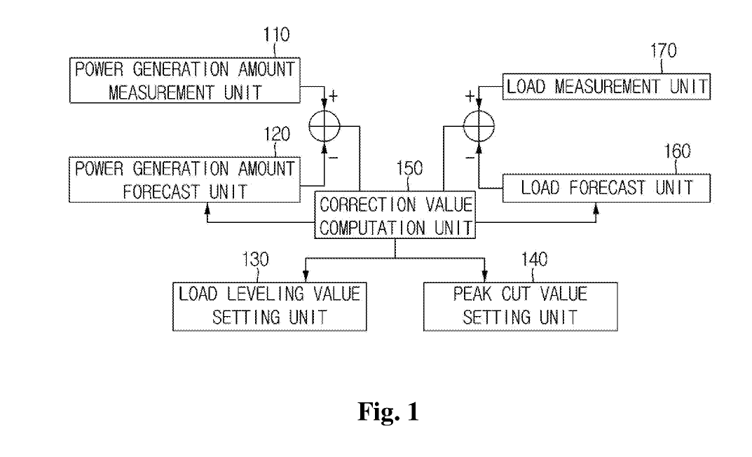

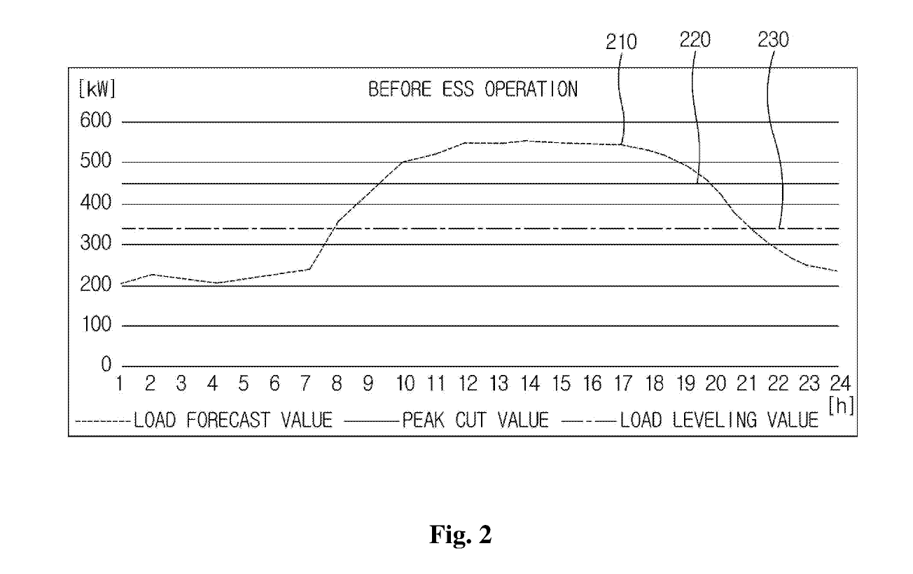

FIG. 1 is a block diagram illustrating a power supply control system according to an embodiment of the invention. FIGS. 2 to 4 are graphs for describing FIG. 1 in details.

The power supply control system according to an embodiment of the invention will now be described with reference to FIGS. 1 to 4.

First, referring to FIG. 1, the power supply control system according to an embodiment of the invention includes a power generation amount measurement unit 110 configured to measure a power generation amount, a power generation amount forecast unit 120 configured to forecast the power generation amount, a load measurement unit 170 configured to measure a load value, a load forecast unit 160 configured to forecast the load value, and a correction value computation unit 150 configured to correct at least one of a peak cut value, a load leveling value, a forecasted power generation amount, a load forecast value on the basis of at least one of a difference between the power generation amount measurement unit 110 and the power generation amount forecast unit 120 and a difference between the load measurement unit 170 and the load forecast unit 160, and an ESS charge/discharge operation output control unit 180 configured to control an output of the ESS charge/discharge operation by applying the correction value computed by the correction value computation unit 150.

Here, the correction value computation unit 150 controls the peak cut value upward and downward to minimize a load consumption peak value by discharging the power of an energy storage system (ESS) at maximum.

An activity ratio is maximized by performing the charge/discharge operation of the ESS as frequent as possible by controlling the load leveling value.

Meanwhile, the correction value computation unit 150 performs control by correcting the forecasted power generation amount and the load forecast value in real time to match the actual power generation amount and the actual load measurement value, respectively, in order to efficiently control the charge/discharge operation and the grid power of the ESS.

FIG. 2 is a graph illustrating a load forecast value, a peak cut value, and a load leveling value set in advance before ESS operation. Here, the load forecast value 210 is a value for forecasting the load through a statistical analysis and may be computed a day ago to control the power supply control system.

The peak cut value 220 is a reference value for supplying power to the load by discharging power from the ESS when the actual load is larger than the peak cut value 220.

Meanwhile, the load leveling value 230 is a value for constantly maintaining the grid power by charging electricity to the ESS when the actual load is equal to smaller than the load leveling value 230. In this case, the ESS can be charged with power remaining after being supplied to the load.

When the actual load is between the load leveling value 230 and the peak cut value 220, the ESS does not perform the charge/discharge operation, and the grid power is supplied to the load.

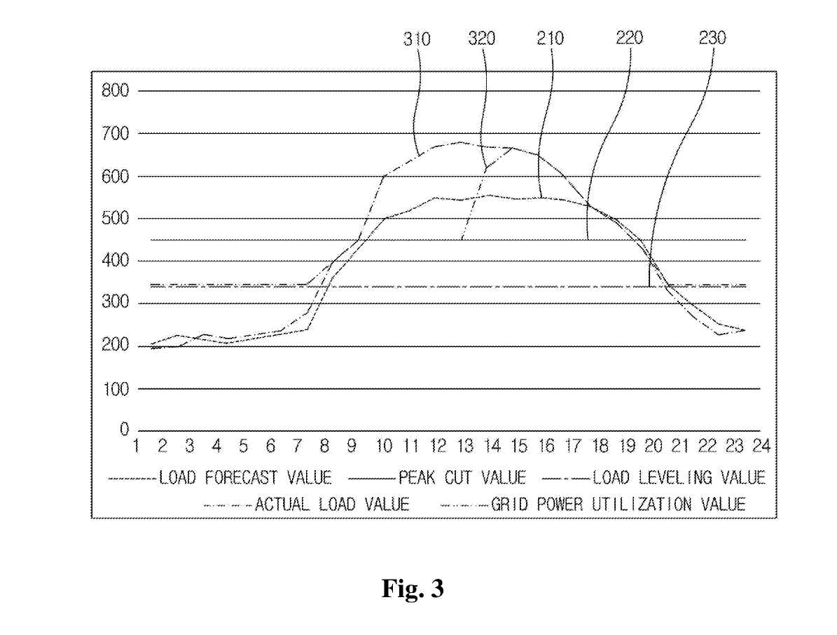

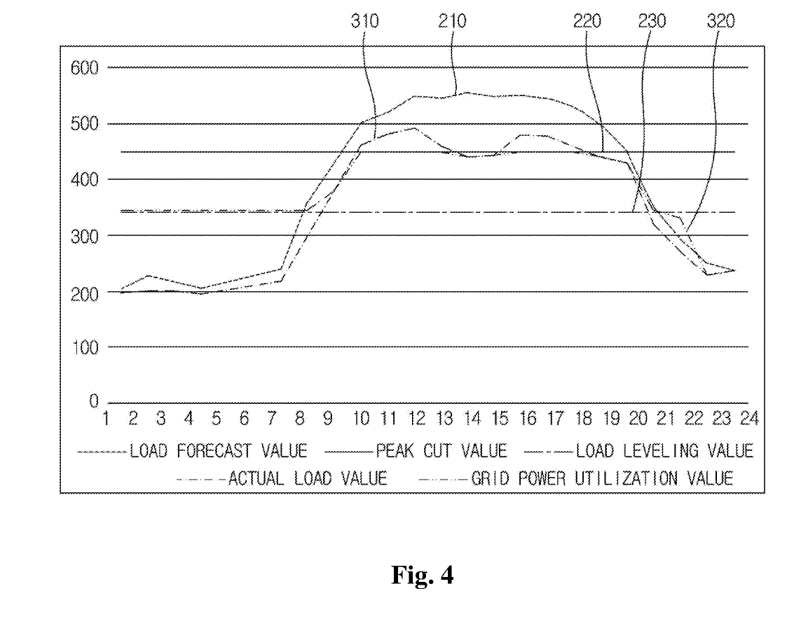

Next, a situation that may occur when the peak cut value 220 is not set optimally will be described with reference to FIGS. 3 and 4.

FIG. 3 is a graph illustrating a case where the load measurement value is larger than the load forecast value after ESS operation. As recognized from FIG. 3, if the actual load value 310 is larger than the load forecast value 210, the power of the ESS is discharged more than forecasted, and a full discharge state is generated earlier.

In this case, if the ESS is fully discharged, the peak-cut operation of the ESS is not appropriately performed.

Therefore, it is necessary to increase the peak cut value 220 depending on a change of the actual load value 310.

Meanwhile, FIG. 4 is a graph illustrating a case where the load measurement value is smaller than the load forecast value after ESS operation. As recognized from FIG. 4, if the actual load value 310 is smaller than the load forecast value 210, the power of the ESS is not sufficiently discharged, and surplus power is generated, so that the activity ratio of the ESS is degraded.

In this case, it is necessary to appropriately decrease the peak cut value 220 depending on a change of the actual load value 310.

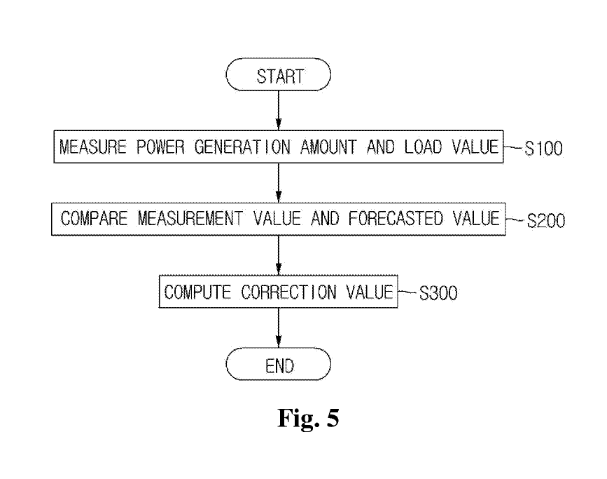

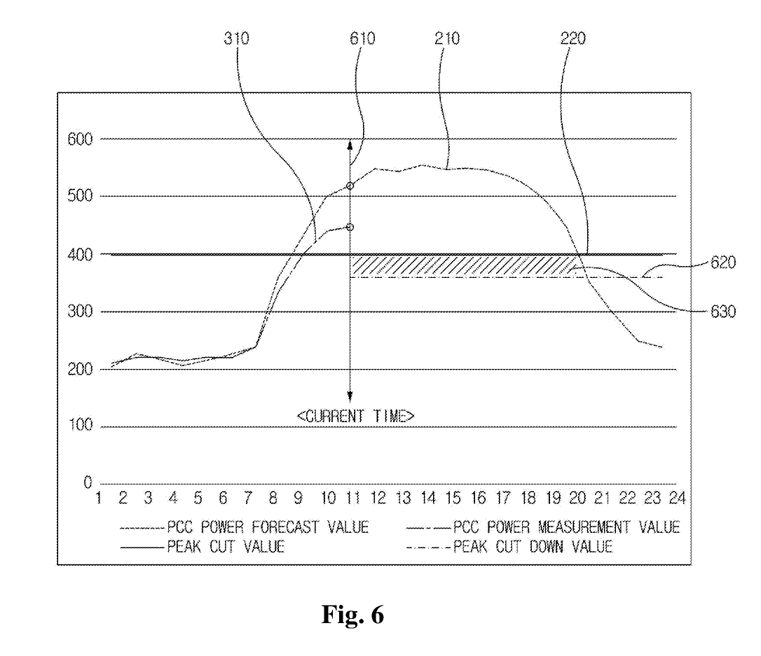

FIG. 5 is a flowchart illustrating a power supply control method according to an embodiment of the invention, and FIGS. 6 to 15 are graphs and flowcharts for describing FIG. 5 in details.

A power supply control method according to another embodiment of the invention will now be described with reference to FIGS. 5 to 15.

First, referring to FIG. 5, the power supply control method according to another embodiment of the invention includes a measurement process S100 for measuring a power generation amount and a load value, a comparison process S200 for comparing the power generation amount and the load value measured in the measurement process S100 with a forecasted power generation amount and a load forecast value forecasted in advance, a correction value computation process S300 for correcting at least one of the peak cut value, the load leveling value, the forecasted power generation amount, and the load forecast value on the basis of a result of the comparison in the comparison process S200, and an ESS charge/discharge operation output control process S400 for controlling an output of the ESS charge/discharge operation by applying the correction value computed in the correction value computation process S300.

Here, in the correction value computation process S300, the peak cut value is controlled upward or downward to discharge the power of the ESS at maximum and minimize a load consumption peak value.

In addition, the load leveling is controlled to perform the ESS charge/discharge operation as sufficient as possible to maximize the activity ratio of the ESS.

Meanwhile, in the correction value computation process S300, the forecasted power generation amount and the load forecast value are corrected in real time to approach the actual power generation amount and the actual load in order to efficiently control the ESS charge/discharge operation and the grid power.

FIG. 6 is a graph for describing a method of performing a peak cut-down operation through correction in the correction value computation process S300 of FIG. 5. As recognized from FIG. 6, the actual load value 310 is smaller than the load forecast value 210 at the current time 610, and it is predicted that only a part of the power of the ESS is discharged. Therefore, if a measurement battery discharge value obtained by accumulating the actual load value 310 for a predetermined period of time is smaller than a battery discharge forecast value, the discharge amount of the ESS can increase by decreasing the peak cut value by a predetermined level.

Here, the predetermined value to be adjusted may be set depending on an installation field or situation of the power supply system, and this will similarly apply to the following description herein.

A predicted remaining amount after battery discharge refers to a predicted battery power remaining in the battery after the ESS discharge operation. The predicted remaining amount after battery discharge can be forecasted on the basis of the actual load value 310 accumulated for a predetermined period of time until the current time 610. An additional discharge amount 630 in the peak cut-down operation refers to a discharge amount that can be additionally discharged when the peak cut value 220 is lowered to a peak cut-down value 620.

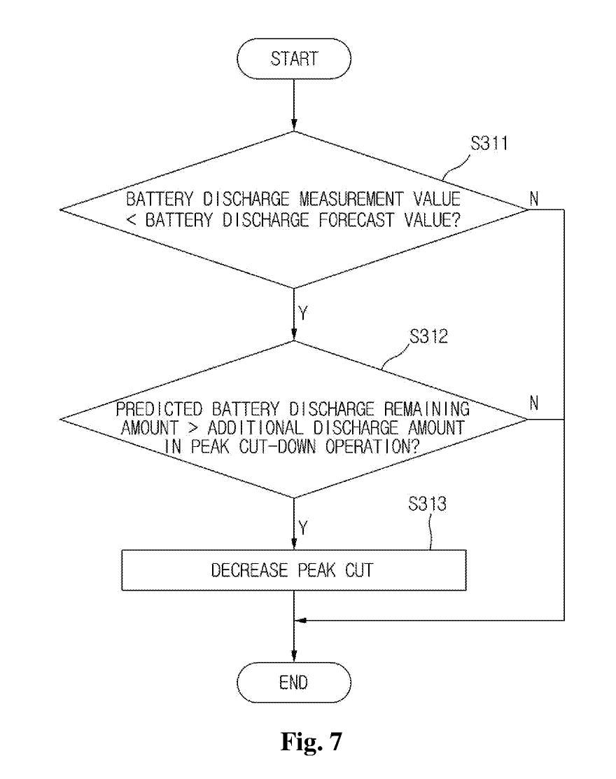

FIG. 7 is a flowchart for describing a method of performing the peak cut-down operation through correction in the correction value computation process S300 of FIG. 5.

As recognized from FIG. 7, the correction value computation process S300 includes a battery discharge measurement value comparison process S311 for checking whether or not the the battery discharge measurement value is smaller than the battery discharge forecast value, a predicted remaining supply amount determination process S312 that checks whether or not the predicted remaining amount after battery discharge is larger than an additional discharge amount in the peak cut-down operation, and a peak cut decreasing process S313 for decreasing the peak cut value by a predetermined level if the battery discharge measurement value is smaller than the battery discharge forecast value, and the predicted remaining amount after battery discharge is larger than the additional discharge amount in the peak cut-down operation.

Therefore, by decreasing the peak cut value in the peak cut decreasing process S313, it is possible to improve the activity ratio of the ESS by increasing the discharge amount of the ESS.

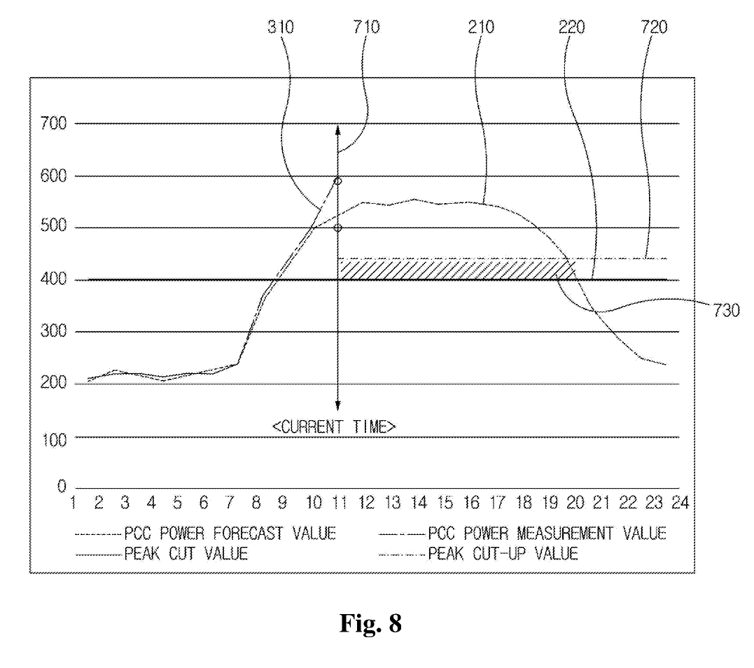

FIG. 8 is a graph for describing a method of performing a peak cut-up operation through correction in the correction value computation process S300 of FIG. 5. As recognized from FIG. 8, if the actual load value 310 is larger than the load forecast value 210 at the current time 710, and the power of the ESS is fully discharged earlier, the peak cut may not be performed appropriately. Therefore, if the battery discharge measurement value obtained by accumulating the actual load value 310 for a predetermined period of time is larger than the battery discharge forecast value, the discharge amount of the ESS can be reduced by increasing the peak cut value by a predetermined level.

In this case, the predicted battery supply deficiency amount refers to a deficiency amount predicted due to supply deficiency after the ESS is discharged. The predicted battery supply deficiency amount may be forecasted by accumulating the actual load value 310 for a predetermined period of time until the current time 710. A discharge reduction amount 730 in the peak cut-up operation refers to a discharge reduction amount reduced by increasing the peak cut value 220 to the peak cut-up value 720.

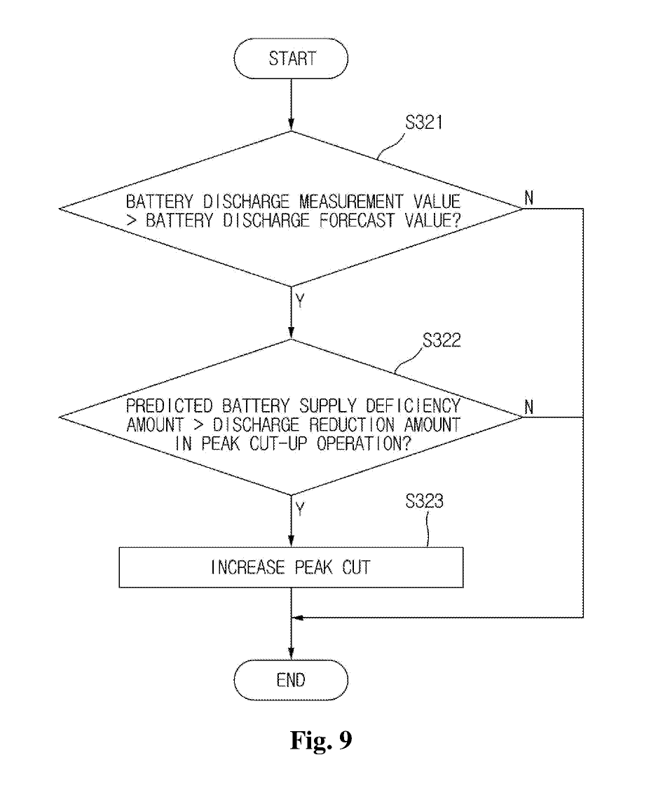

FIG. 9 is a flowchart for describing a method of performing a peak cut-up operation through correction in the correction value computation process S300 of FIG. 5.

As recognized from FIG. 9, the correction value computation process S300 includes a battery discharge measurement value comparison process S321 for checking whether or not the battery discharge measurement value is larger than the battery discharge forecast value, a predicted supply deficiency amount determination process S322 for checking whether or not the predicted battery supply deficiency amount is larger than the discharge reduction amount in the peak cut-up operation, and a peak cut increasing process S323 for increasing the peak cut value by a predetermined level if the battery discharge measurement value is larger than the battery discharge forecast value, and the predicted battery supply deficiency amount is larger than the discharge reduction amount in the peak cut-up operation.

Therefore, by increasing the peak cut value in the peak cut increasing process S323, it is possible to reduce the discharge amount of the ESS, prevent the power of the ESS from being fully discharged earlier, and appropriately perform the peak cut operation of the ESS.

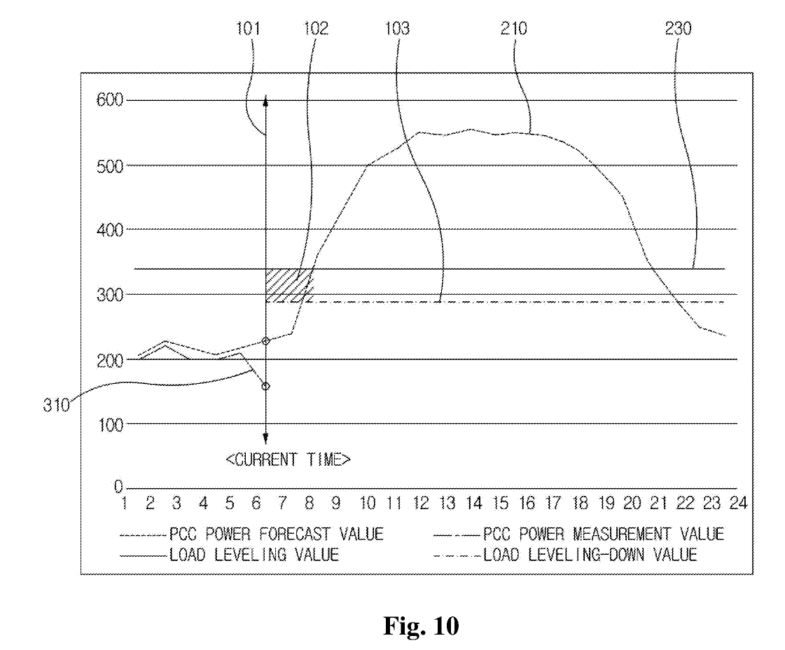

FIG. 10 is a graph for describing a method of performing a load leveling-down operation through correction in the correction value computation process S300 of FIG. 5. As recognized from FIG. 10, at the current time 101, the actual load value 310 is smaller than the load forecast value 210, and the power to be charged to the ESS increases as much as a difference between the load leveling value 230 and the actual load value 310, so that the ESS may be overcharged. Therefore, if the battery discharge measurement value obtained by accumulating the actual load value 310 for a predetermined period of time is larger than the battery discharge forecast value, the charge amount to the ESS can be reduced by increasing the load leveling value by a predetermined level.

In this case, the predicted battery overcharge amount refers to a predicted surplus amount caused by overcharging the ESS. The predicted battery overcharge amount can be predicted by accumulating the actual load value 310 for a predetermined period of time until the current time 101. The load leveling-down charge reduction amount 102 refers to a charge reduction amount reduced by decreasing the load leveling value 230 to a load leveling-down value 103.

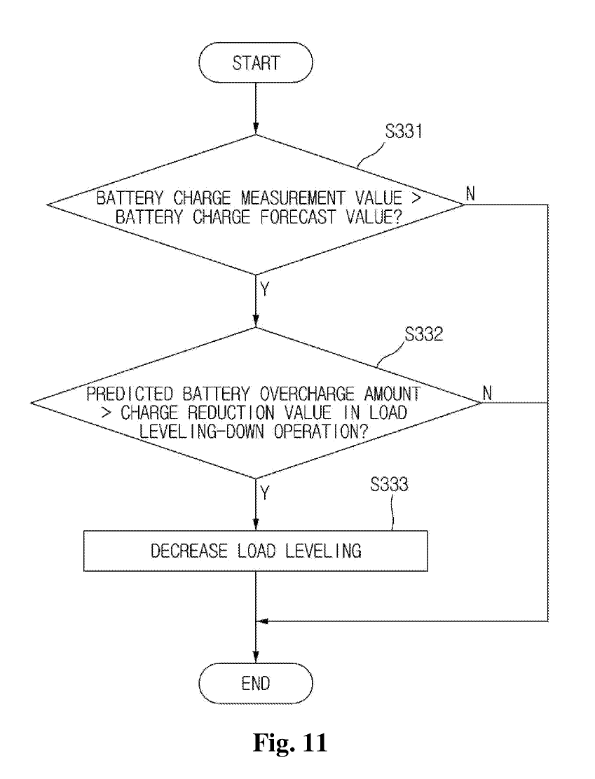

FIG. 11 is a flowchart for describing a method of performing a load leveling-down operation through correction in the correction value computation process S300 of FIG. 5.

As recognized from FIG. 11, the correction value computation process S300 includes a battery charge measurement value comparison process S331 for checking whether or not the battery charge measurement value is larger than the battery charge forecast value, a predicted battery overcharge amount determination process S332 for checking whether or not the predicted battery overcharge amount is larger than the charge reduction amount caused by load leveling-down operation, and a load leveling decreasing process S333 for decreasing the load leveling value by a predetermined level if the battery charge measurement value is larger than the battery charge forecast value, and the predicted battery overcharge amount is larger than the charge reduction amount in the load leveling-down operation.

Therefore, by decreasing the load leveling in the load leveling decreasing process S333, it is possible to reduce the charge amount to the ESS, prevent the ESS from being overcharged, and efficiently operate the power supply control system.

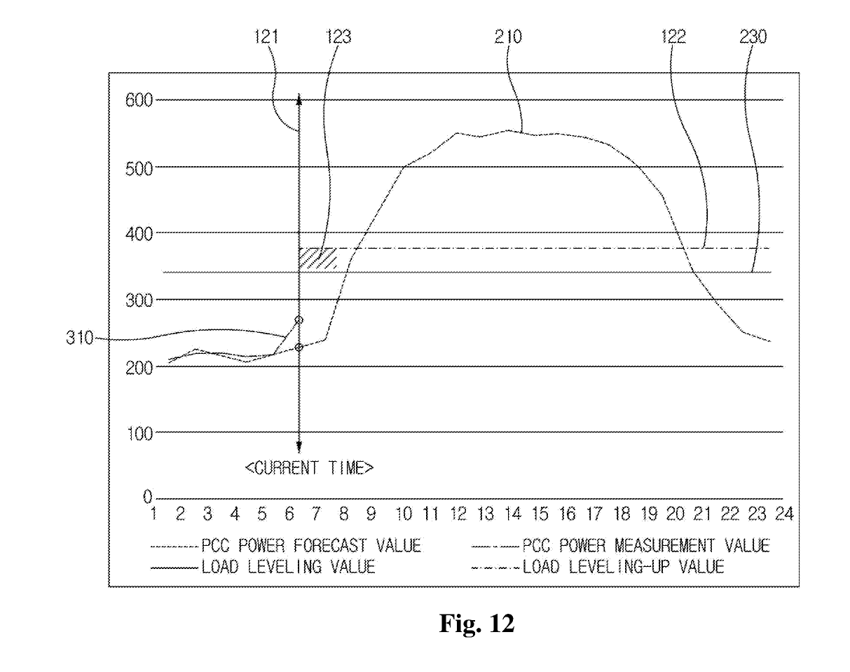

FIG. 12 is a graph for describing a method of performing a load leveling-up operation through correction in the correction value computation process S300 of FIG. 5. As recognized from FIG. 12, at the timing 121, the actual load value 310 is larger than the load forecast value, and the power charged to the ESS is reduced by a difference between the load leveling value 230 and the actual load value 310, so that the ESS may be insufficiently charged. Therefore, it is possible to increase the charge amount to the ESS by increasing the load leveling if the battery discharge measurement value obtained by accumulating the actual load value 310 for a predetermined period of time is smaller than the battery discharge forecast value.

In this case, the predicted battery charge deficiency amount refers to a charge predicted deficiency amount in the ESS. The predicted battery charge deficiency amount may be forecasted by accumulating the actual load value 310 for a predetermined period of time until the current time 121. The load leveling-up charge increase amount 123 refers to a charge increase amount by increasing the load leveling value 230 to the load leveling-up value 122.

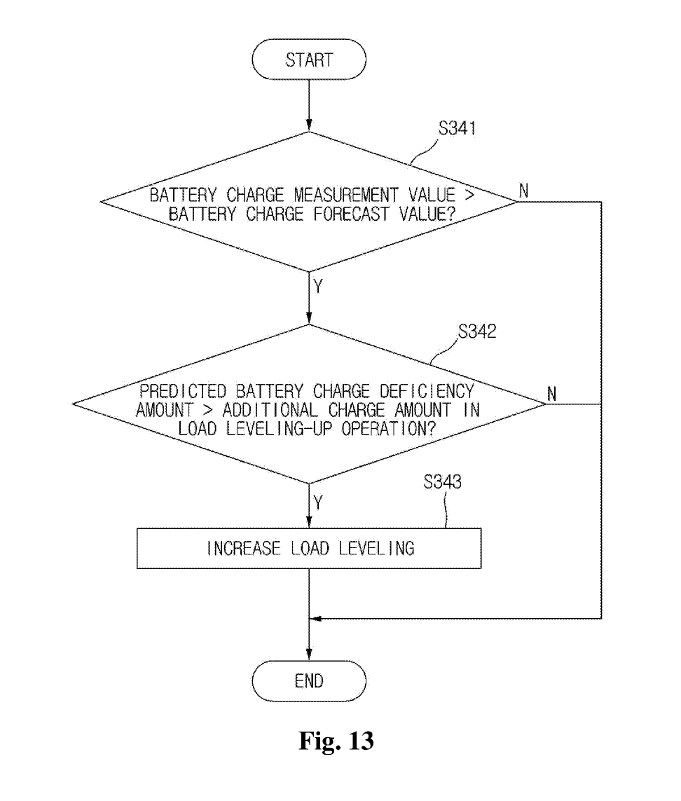

FIG. 13 is a flowchart for describing a method of performing a load leveling-up operation through correction in the correction value computation process S300 of FIG. 5.

As recognized from FIG. 13, the correction value computation process S300 includes a battery charge measurement value comparison process S341 for checking whether or not the battery charge measurement value is smaller than the battery charge forecast value, a predicted charge deficiency amount determination process S342 for checking whether or not a predicted battery deficiency charge amount is larger than the additional charge amount in the load leveling-up operation, and a load leveling increasing process S343 for increasing the load leveling value by a predetermined level if the battery charge measurement value is smaller than the battery charge forecast value, and the predicted battery deficiency charge amount is larger than the additional charge amount in the load leveling-up operation.

Therefore, by increasing the load leveling in the load leveling increasing process S343, it is possible to increase the charge amount to the ESS, prevent the ESS from being insufficiently charged, and improve an activity ratio of the ESS.

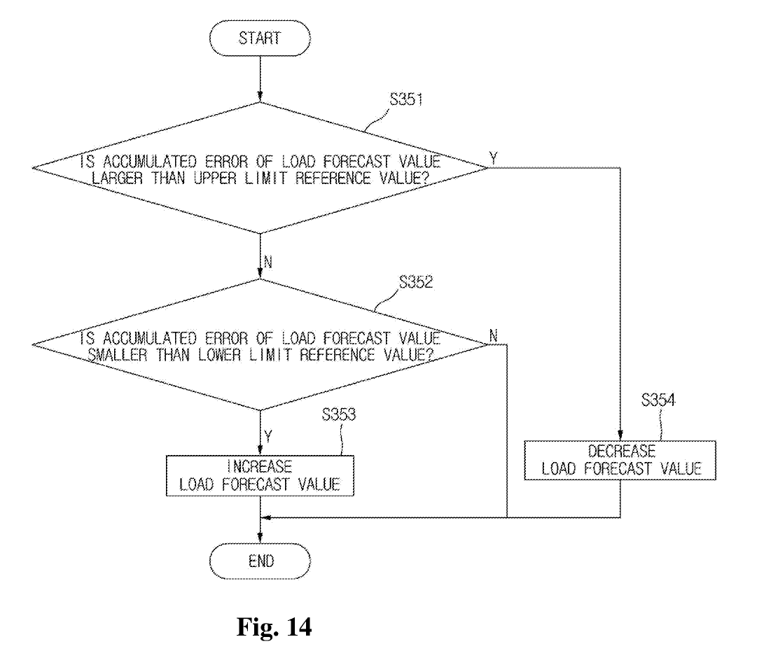

FIG. 14 is a flowchart for describing a method of adjusting the load forecast value through correction in the correction value computation process S300 of FIG. 5.

As recognized from FIG. 14, the correction value computation process S300 includes a load forecast value upper limit excess check process S351 for checking whether or not an accumulated error of the load forecast value is larger than an upper limit reference value, and a load forecast value decreasing process S354 for decreasing the load forecast value by a predetermined level if the accumulated error of the load forecast value is larger than the upper limit reference value.

The correction value computation process S300 includes a load forecast value lower limit shortage check process S352 for checking whether or not the accumulated error of the load forecast value is smaller than a lower limitation reference value, and a load forecast value decreasing process S353 for decreasing the load forecast value by a predetermined level if the accumulated error of the load forecast value is smaller than the lower limit reference value.

Here, the accumulated error of the load forecast value may be a value obtained by accumulating and averaging the load forecast value and the actual load value for a predetermined period of time.

If the accumulated error of the load forecast value is larger than the upper limit reference value, this means that the forecasted load is excessively large. Therefore, it is necessary to decrease the load forecast value. Otherwise, if the accumulated error of the load forecast value is smaller than the lower limit reference value, this means that the forecasted load is excessively small. Therefore, it is necessary to increase the load forecast value.

By appropriately performing the peak cut operation and the load leveling operation by adjusting the load forecast value on the basis of the accumulated error of the load forecast value, it is possible to efficiently operate the ESS and the power supply control system.

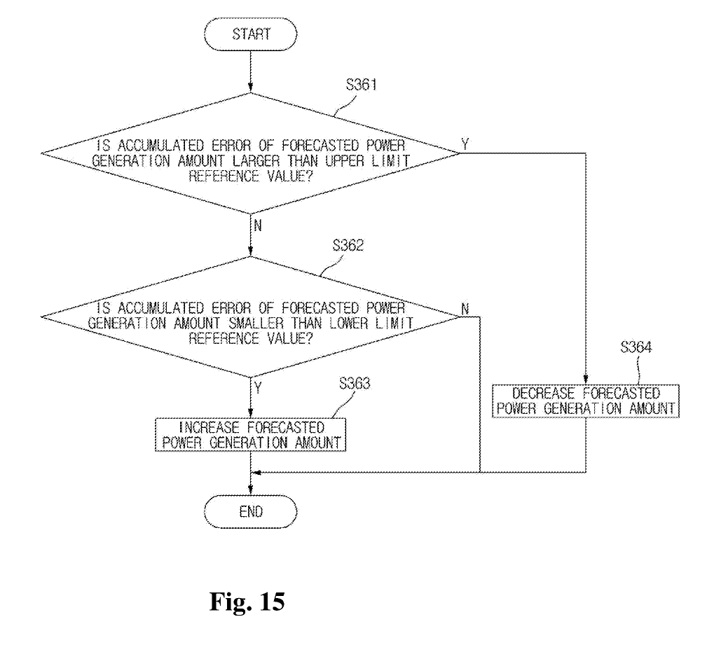

FIG. 15 is a flowchart for describing a method of adjusting the forecasted power generation amount through correction in the correction value computation process S300 of FIG. 5.

As recognized from FIG. 15, the correction value computation process S300 includes a forecasted power generation amount upper limit excess check process S361 for checking whether or not an accumulated error of the forecasted power generation amount is larger than an upper limit reference value, and a forecasted power generation amount decreasing process S364 for decreasing the forecasted power generation amount by a predetermined level if the accumulated error of the forecasted power generation amount is larger than the upper limit reference value.

In addition, the correction value computation process S300 includes a forecasted power generation amount lower limit shortage check process S362 for checking whether or not an accumulated error of the forecasted power generation amount is smaller than a lower limit reference value, and a forecasted power generation amount increasing process S363 for increasing the forecasted power generation amount by a predetermined level if the accumulated error of the forecasted power generation amount is smaller than the lower limit reference value.

Here, the accumulated error of the forecasted power generation amount for the power generation amount generated from renewable energy such as solar energy and wind energy may be obtained by accumulating and averaging a difference between the forecasted power generation amount and the actual power generation amount for a predetermined period of time.

If the accumulated error of the forecasted power generation amount is larger than an upper limit reference value, this means that the forecasted power generation amount is excessively large. Therefore, it is necessary to decrease the forecasted power generation amount. Otherwise, if the accumulated error of the forecasted power generation amount is smaller than the lower limit reference value, this means that the forecasted power generation amount is excessively small. Therefore, it is necessary to increase the forecasted power generation amount.

By appropriately performing the peak cut operation and the load leveling operation by adjusting the forecasted power generation amount on the basis of the accumulated error of the forecasted power generation amount, it is possible to efficiently operate the ESS and the power supply control system.

As described above, using the power supply control method and system according to the present invention, it is possible to effectively lower the load peak value by adjusting the peak cut value depending on a field situation based on the current load measurement value and the power generation amount measurement value. In addition, it is possible to maximize an activity ratio of the ESS by adjusting the load leveling value depending on a field situation.

Although exemplary embodiments of the present invention have been shown and described hereinbefore, it will be apparent to those having ordinary skill in the art that a number of changes, modifications, or alterations to the invention as described herein may be made, none of which depart from the spirit of the present invention. All such changes, modifications and alterations should therefore be seen as within the scope of the present invention.

The present invention is applicable to all fields relating to a power supply control method and system and an energy storage system (ESS).

1. A power supply control method comprising:
a measurement process for measuring a power generation amount and a load value;
a comparison process for comparing the power generation amount and the load value measured by the measurement process with a forecasted power generation amount and a load forecast value forecasted in advance;
a correction value computation process for correcting at least one of, a peak cut value, a load leveling value, the forecasted power generation amount, and the load forecast value on the basis of a result of the comparison of the comparison process; and
an energy storage system (ESS) charge/discharge operation output control process for controlling an output of an ESS charge/discharge operation by applying a correction value computed in the correction value computation process.

2. The power supply control method according to claim 1, wherein the correction value computation process has
a battery discharge measurement value comparison process for checking whether or not a battery discharge measurement value is smaller than the battery discharge forecast value,
a predicted remaining supply amount determination process for checking whether or not a predicted remaining amount after battery discharge is larger than an additional discharge amount in a peak cut-down operation, and
a peak cut decreasing process for decreasing the peak cut value by a predetermined level if the battery discharge measurement value is smaller than the battery discharge forecast value, and the predicted remaining amount after battery discharge is larger than the additional discharge amount in the peak cut-down operation.

3. The power supply control method according to claim 1, wherein the correction value computation process has
a battery discharge measurement value comparison process for checking whether or not the battery discharge measurement value is larger than the battery discharge forecast value,
a predicted supply deficiency amount determination process for checking whether or not a predicted battery supply deficiency amount is larger than a discharge reduction amount in a peak cut-up operation, and
a peak cut increasing process for increasing the peak cut value by a predetermined level if the battery discharge measurement value is larger than the battery discharge forecast value, and the predicted battery supply deficiency amount is larger than the discharge reduction amount in the peak cut-up operation.

4. The power supply control method according to claim 1, wherein the correction value computation process has
a battery charge measurement value comparison process for checking whether or not a battery charge measurement value is larger than a battery charge forecast value,
a predicted battery overcharge amount determination process for checking whether or not a predicted battery overcharge amount is larger than the a charge reduction amount in a load leveling-down operation, and
a load leveling decreasing process for decreasing the load leveling value by a predetermined level if the battery charge measurement value is larger than the battery charge forecast value, and the predicted battery overcharge amount is larger than the charge reduction amount in the load leveling-down operation.

5. The power supply control method according to claim 1, wherein the correction value computation process has
a battery charge measurement value comparison process for checking whether or not a battery charge measurement value is smaller than a battery charge forecast value,
a predicted charge deficiency amount determination process for checking whether or not a predicted battery deficiency charge amount is larger than an additional charge amount in a load leveling-up operation, and
a load leveling increasing process for increasing the load leveling value by a predetermined level if the battery charge measurement value is smaller than the battery charge forecast value, and the predicted battery deficiency charge amount is larger than an additional charge amount in the load leveling-up operation.

6. The power supply control method according to claim 1, wherein the correction value computation process has
a load forecast value upper limit excess check process for checking whether or not an accumulated error of the load forecast value is larger than an upper limit reference value, and
a load forecast value decreasing process for decreasing the load forecast value by a predetermined level if the accumulated error of the load forecast value is larger than the upper limit reference value.

7. The power supply control method according to claim 1, wherein the correction value computation process has
a load forecast value lower limit shortage check process for checking whether or not an accumulated error of the load forecast value is smaller than a lower limit reference value, and
a load forecast value increasing process for increasing the load forecast value by a predetermined level if the accumulated error of the load forecast value is smaller than the lower limit reference value.

8. The power supply control method according to claim 1, wherein the correction value computation process has
a forecasted power generation amount upper limit excess check process for checking whether or not an accumulated error of the forecasted power generation amount is larger than an upper limit reference value, and
a forecasted power generation amount decreasing process for decreasing the forecasted power generation amount by a predetermined level if the accumulated error of the forecasted power generation amount is larger than the upper limit reference value.

9. The power supply control method according to claim 1, wherein the correction value computation process has
a forecasted power generation amount lower limit shortage check process for checking whether or not an accumulated error of the forecasted power generation amount is smaller than a lower limit reference value, and
a forecasted power generation amount increasing process for increasing the forecasted power generation amount by a predetermined level if the accumulated error of the forecasted power generation amount is smaller than the lower limit reference value.

10. A power supply control system comprising:
a power generation amount measurement unit configured to measure a current power generation amount value;
a power generation amount forecast unit configured to forecast a power generation amount value;
a load measurement unit configured to measure a current load value;
a load forecast unit configured to forecast a load value;
a correction value computation unit configured to correct at least one of a peak cut value, a load leveling value, the forecasted power generation amount, and the load forecast value on the basis of at least one of a difference between the power generation amount measurement unit and the power generation amount forecast unit and a difference between the load measurement unit and the load forecast unit; and
an ESS charge/discharge operation output control unit configured to control an output of an ESS charge/discharge operation by applying a correction value computed by the correction value computation unit.
